(19) United States
(12) Patent Application Publication
(10) Pub. No.: US 2002/0167422 A1
(43) Pub. Date: Nov. 14, 2002

(54) Device for controlling a three-dimensional movement

(76) Inventors: Jacques Andre, Waterloo (BE); Roland Polet, Marche-En-Famennes (BE)

Correspondence Address: KNOBBE MARTENS OLSON & BEAR LLP, 2040 MAIN STREET, FOURTEENTH FLOOR, IRVINE, CA, 91614, US

(21) Appl. No.: 10/127,344

(22) Filed: Apr. 19, 2002

(30) Foreign Application Priority Data
Apr. 27, 2001 (EP) 01 870 092.2

(51) Int. Cl. H03M 11/00; H03K 17/94

(52) U.S. Cl. 341/34

(57) ABSTRACT

The present invention is related to a device for translating spatial movements of a finger of the user of said device, into spatial movements of an object in wired or wireless connection with said device, said device comprising a command part which is connected by electrical connections to a transmission part, wherein said command part is in physical contact only with the first phalanx of said finger and comprises means which allow it to be held against an essentially rigid surface, during operation of said device.

### CROSS-REFERENCE TO RELATED APPLICATIONS

This application claims priority to European Application 01 870 092.2, filed Apr. 27, 2001, the disclosure of which is herein incorporated by reference in its entirety.

### BACKGROUND OF THE INVENTION

1. Field of the Invention

The present invention is related to a device for controlling a three-dimensional movement, such as a mouse or joystick.

2. Description of the Related Art

Devices such as a mouse or a joystick are generally able to command a movement in two dimensions, meaning in the direction of two orthogonal axes, X and Y. Some types of joysticks provide the additional control of the movement along a third (Z) axis, perpendicular to the other two. These latter devices normally have two buttons, each one commanding the movement in one or the other direction along said third axis. These buttons, which can be placed next to a joystick make it necessary for the user operating the device, to remove his hand or foot or at least one finger from the device, in order to select the direction to be used. In other cases, several members, e.g. several fingers need to be used in order to combine the control of the two-dimensional movement with that of the Z-movement.

Document JP11154031 describes a joy stick capable of inputting components of three systems at a time with one finger. This is done by an operation ring into which a finger or arm is inserted. In the common case, this member is the thumb and the ring is placed on top of the joystick. Moving the thumb up- or downwards is then equal to selecting the movement in either direction along the third axis. This design mainly has a security problem in some applications, in particular medical applications (command of laprascopic equipment). The main problem is the fact that the finger or arm controlling the sixth movement cannot easily or quietly be removed from the ring. Also, the movement of the thumb in an upward direction is not easily maintained for long periods of time, i.e. this movement is not ergonomic and will lead to errors which are unacceptable in medical applications.

The document WO9808062is related to a manually operated signaling apparatus comprising an actuating device adapted to be secured to one finger of the user's hand and to be operated by another finger or thumb.

The document U.S. Pat. No. 5,625,576 is related to a connection element such as a thimble, connecting to a user's body member and, through a linkage, to a ground reference.

### SUMMARY OF THE INVENTION

The present invention provides a device for controlling a three-dimensional movement, having none of the disadvantages of the prior art.

The present invention is related to a device for translating spatial movements of a finger of the user of the device, into spatial movements of an object in wired or wireless connection with said device. The movements take place in a maximum of six directions (+X, −X, +Y, −Y, +Z, −Z), each direction being parallel to one of three orthogonal axes (X, Y, Z). The device includes a command part which is connected by electrical connections to a transmission part, so that the command part is in physical contact only with the first phalanx of the finger, during operation of the device.

The command part includes an element which allows it to be strapped around the phalanx, and held by the phalanx against an essentially rigid surface, during operation of the device.

According to an embodiment of a device according to the invention, the command part includes a semi-rigid part that fits on the user's finger's first phalanx, a flexible part enveloping both the semi-rigid part and the phalanx and making contact with the surface, a first contact, an electrically conducting lever in permanent contact with the first contact, a cylinder-like enclosure placed around the lever and rigidly connected to the semi-rigid part, and comprising up to four electrically conducting zones, separated by narrow slits, wherein the contacting of each zone with the lever generates the appearance of an electrically conducting path comprising the lever, the zone and the first contact, a second contact placed above the lever, so that pressing down the command part on the surface generates a second electrically conducting path comprising the first contact, the second contact and the lever, a spring, allowing the interruption of the second electrically conducting path, as soon as the pressure is released.

The invention is equally related to the same device, further comprising a third and fourth contact, being brought into contact with each other by placing the phalanx flat onto the surface, thereby generating an electrically conducting path.

In a particular embodiment of the invention, the activation of the contacting zones is related to movements in the directions left, right, in and out, relative to the user. Activation of the second contact is related to movement in the ‘down’ direction, relative to the user, and the third and fourth contact are related to the ‘up’ movement relative to the user.

According to another embodiment of the invention, the movement in at least one direction is commanded by vocal commands. The second contact allows enabling or disabling of the vocal command of a movement in the at least one direction.

### BRIEF DESCRIPTION OF THE DRAWINGS

FIG. 1 illustrates the six directions of movement to be controlled by a device according to the invention.

FIGS. 2a and 2b show two views of a preferred embodiment of the device according to the present invention.

FIGS. 3a and 3b illustrate a detailed view of the preferred embodiment of a device according to the present invention.

FIG. 4 illustrates another view of the preferred embodiment of the present invention.

### DETAILED DESCRIPTION OF THE PREFERRED EMBODIMENT

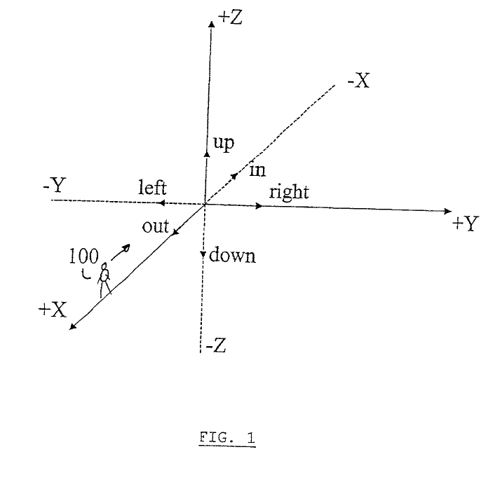

The present invention is related to a device allowing the control of a three-dimensional movement by the user of such a device. With a device according to the invention, movement along three axes may be commanded by movements of the user's finger, the characteristic in all embodiments being that the device comprises a command part which is in physical contact with the first phalanx of one finger, and which comprises means which allow the command part to be held against an essentially rigid surface. Any one of the five fingers may be used for such a control. In particular, the movement is controlled in a maximum of six directions, being either the positive or the negative of one of three orthogonal axes X, Y, Z (FIG. 1). In many applications, these directions are more conveniently named left-right/up-down/in-out, depending on the viewpoint of the operator 100 of the device according to the invention, see also FIG. 1. According to a special embodiment, the movement in a number of these directions may be controlled by other means, in particular by voice control.

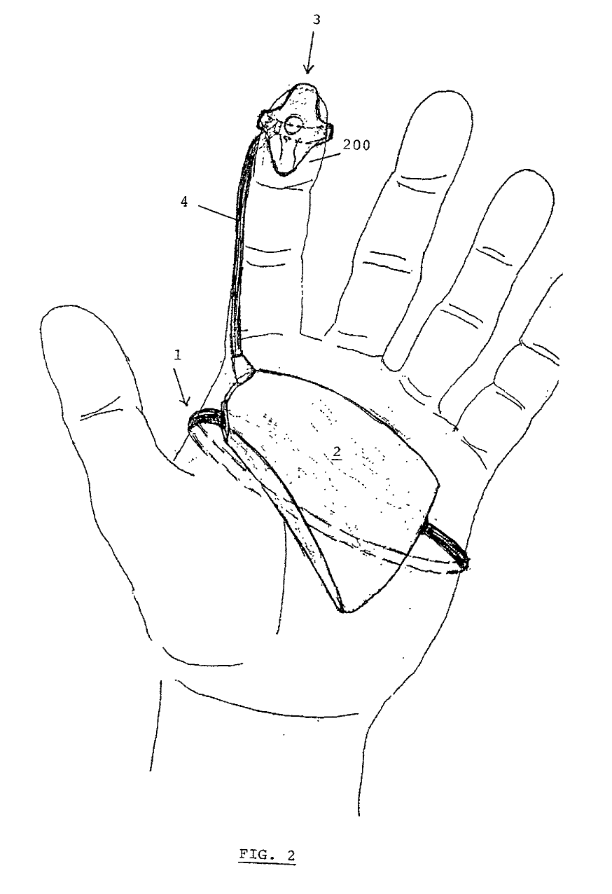

FIG. 2 shows a first preferred embodiment of the invention. The device 1 is strapped around the user's hand. A central part 2 is covering the wearer's palm, while the command part 3 is attached to the user's finger, preferably the index finger. The command part 3 is more particularly strapped around the first phalanx 200 of the user's finger. Electrical connections 4 are present between the command part 3 and the central part 2, the latter containing means for sending command signals by wireless transmission to a tool or device such as a laprascopic instrument. Such command signals are then directly related to the signals originating in the command part 3.

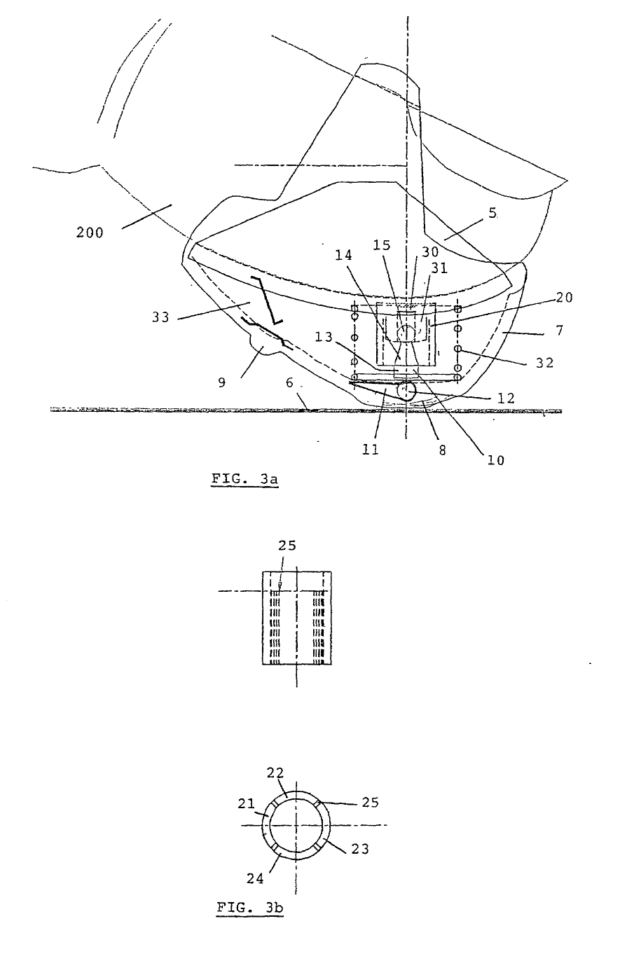

FIG. 3a shows a detailed cross-sectional view of this command part 3. First of all, the command part consists of a semi-rigid sub-part 5, that fits on the user's finger's first phalanx 200, as shown in the drawing. Enveloping the finger and making contact with a hard surface 6, is a flexible sub-part 7, comprising on its downside surface two bulging areas 8 and 9. The device is actuated by placing it against the hard surface 6 and making spatial movements with the finger, while maintaining contact with the surface 6 in the same point. In the position shown in FIG. 3a, movement in five directions can be actuated: up-down, left-right and in. The material of the flexible sub-part 7 is such that considerable friction exists between this sub-part 7 and the rigid surface 6, this way allowing spatial movements of the semi-rigid sub-part 5 relative to the flexible sub-part 7, for example when the finger is pushed forward. During such movements, the contact between part 7 and the surface 6 should be retained in the same contact point.

The first four movements are actuated with the help of a small electrically conducting lever 10, in connection with a first contact 11. The lever comprises a base part 12 which is ball-shaped and which is embedded in the flexible sub-part 7, and making permanent contact with the first contact 11. On top of that, a straight portion 13, a cone shaped portion 14 and a top portion 15 are present, the latter being equally ball-shaped. The lever 10 is installed inside a cylinder-shaped enclosure 20, enabling the second contact. This enclosure 20 is placed underneath and fixed to the rigid part 5 on which the user's finger rests. FIG. 3b shows a frontal and plan cross sectioned view of the enclosure 20, which is made up of four electrically conducting zones 21,22,23,24, separated by narrow slits 25.

Each of the four zones is dedicated to the command of movement in one of four directions, preferably left-right and in-out, and four wires (not shown) are connected to these zones, allowing the transmittal of a signal which is relative to a movement in each of these directions to the transmitting device inside the central support 2. The contact is made by the user's movements: by moving his finger from back to front for example, while maintaining contact at the same point of the rigid surface 6, he will cause the enclosure 20, which is fixed to the rigid part 5, to tilt in the forward direction compared to the position shown in FIG. 3a. The lever, being balanced on its base portion 12, and connected in no rigid way to the semi-rigid part 5, will be induced to tilt in the opposite direction of the enclosure's movement and the two (enclosure and lever) will make contact at the back of the enclosure, more particularly on zone 21 of the enclosure, supposing that the enclosure's orientation in FIGS. 3a and 3b is the same. This contact, along with the base contact, causes an electrical circuit to close, leading to the transmittal of a signal towards the transmitting device inside the support 2 and eventually towards the driven tool. According to the preferred embodiment, a forward or backward movement of the finger will be translated into a movement of the tool in a plane parallel to the XY-plane and in a direction parallel to the X-axis (in or out) of FIG. 1; a movement in the left or right direction will result in the tool's movement in the left or right direction in said plane parallel to the XY-plane and in a direction parallel to the Y-axis of FIG. 1.

The narrow slits of the enclosure 20 are such that a simultaneous contact between the lever 10 and two adjacent zones is possible. Provision is made for this type of contact to be translated in a simultaneous movement of the tool in two directions.

In the position shown in FIG. 3a, a fifth movement (‘down’, see FIG. 1) may be actuated. This is done by the third contact 30 placed on the inside of a cylinder-like structure 31 enveloping the top ball shaped part 15 of the lever 10. The structure 31 is flexible to maintain a default position of the lever when the contact 30 is released. The structure 31 acts as a guide for the ball-shaped top part 15 of the lever 10, towards the contact 30, while still allowing a tilting movement of said lever around its base portion 12. The contact 30 is activated by the user's finger pushing down on the command device, thereby causing an electrical contact between the lever's top portion 15 and the contact 30. The ‘down’ movement resulting from this contact may be in combination with a movement in one or two of the other directions, if the contact 30 is actuated from one of the tilted positions. A spring 32 necessitates the exertion of a minimum pressure by the user, before the contact 30 is actuated. The spring also allows a quick release of the contact 30 once the user's pressure is removed.

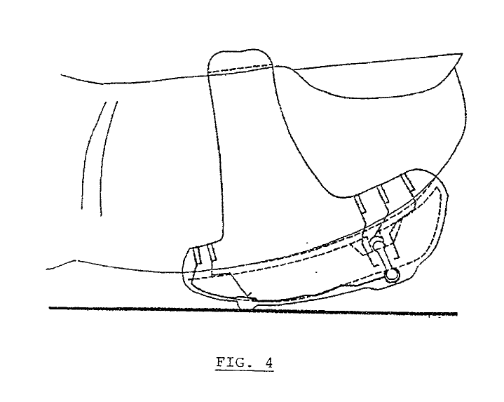

Another pair of contacts 33 is present in the command part, just above the second bulging area 9. By moving the first phalanx 200 into the position shown in FIG. 4, these contacts 33 are activated. Enabling the contacts 33 in this way activates the sixth movement, namely in the ‘out’ direction. During the activation of the ‘out’ movement, all other movements are de-activated.

This device allows a control of the movement in six directions in-out, up-down, left-right, by small movements of one finger. Five directions are controlled by minimal movements of the finger tip, allowing a very accurate control of the object's movements in space. The sixth direction requires a mere tilting of the first phalanx. The user's hand is in no way hampered during operation; a simple lifting of the finger is enough to interrupt the ongoing movements without any delay and thus without errors. The device is very compact and allows a completely wireless operation, thus obviating the necessity of being attached to a device which is to be controlled.

An embodiment derived from the one shown in FIG. 3 controls less than the six directions described. This may be obtained by having less than four conducting zones on the enclosure 20, for example two zones: one contacted by a forward movement, one by a backward movement. The contact 33 may also be left out. A device like that might be used to control a two-dimensional movement, or even a one-dimensional movement.

The contact 11 is preferably made of gold-plated inox. The contacts of the switch 30 are preferably made of gold-plated bronze. The lever is preferably made of gold-plated messing. The spring 32 preferably has four turns, an external diameter between 6.5 mm and 7 mm, and a diameter of the turns of 0.4 mm. According to a preferred embodiment, the height of the envelope 20 is 4.8 mm, while the height of the narrow slits 25 is 3.8 mm. The width of the slits 25 is preferably between 0.2 mm and 0.3 mm. Each slit is preferably at a right angle to the adjacent one. The scale of the device may be as much as halved compared to the dimensions described above.

The device described above is operated by one finger, while the command part is in contact only with said finger's first phalanx 200. More particularly, movement in six directions is commanded by said one finger. The invention is however also related to variants of the above described devices, wherein a number of movements are commanded by other means. These means preferably consist of a vocal command. Known techniques for translating vocal commands into command signals may be used for this. In all devices which have this capability however, an on/off switch has to be present, commanding the activation or the interruption of the vocal command itself. This introduces a security element in the device's operation : for example by pressing a button, the vocal command of a number of movements is enabled, and by releasing said button, this vocal command is disabled.

As an example of such a device, reference is made once more to FIG. 3. The invention is then related to the same device, without the contact 33, and wherein the contact 30 acts as the control of the vocal command. This vocal command may be able to control the up-down movement, for example, while the left-right and in-out movement are still being commanded by the finger movement, as in the previous embodiment. Pushing down on the device, so that contact 30 is activated, allows ‘up-down’ to be controlled vocally. Releasing contact 30 blocks the vocal command.

What is claimed is:

1. A device for translating spatial movements of a finger of the user of the device into spatial movements of an object, the movements taking place in a maximum of six directions (+X, −X, +Y, −Y, +Z, −Z), each direction being parallel to one of three orthogonal axes (X, Y, Z) , said device comprising:
a command part, said command part being in physical contact with the first phalanx of the finger during operation of said device, wherein said command part is strapped around said phalanx and comprises an element allowing the command part to be held by said phalanx against an essentially rigid surface during operation of said device; and
a transmission part connected by electrical connection to the command part.

2. The device of claim 1, wherein said object is in wireless or wired connection with said device.

3. The device of claim 1, wherein said command part is in physical contact only with said first phalanx of said finger.

4. The device of claim 1, wherein said command part comprises:
a semi-rigid part that fits on the first phalanx of the user's finger;
a flexible part enveloping both said semi-rigid part and said phalanx and making contact with said essentially rigid surface;
a first contact;
an electrically conducting lever, in permanent contact with said first contact;
a cylinder-like enclosure placed around said lever and rigidly connected to said semi-rigid part, and comprising up to four electrically conducting zones, separated by narrow slits, wherein the contacting of each zone with said lever generates an electrically conducting path comprising said lever, said zone, and said first contact; and
a second contact placed above said lever placed above said lever so that pressing down said command part on said surface generates a second electrically conducting path comprising said first contact, said second contact and said lever.

5. The device of claim 4, further comprising a spring which allows the interruption of said second electrically conducting path when said pressure is released.

6. The device of claim 4, further comprising a third and fourth contact being brought into contact with each other by placing the phalanx flat onto the surface, thereby generating an electrically conducting path.

7. The device of claim 6, wherein activation of said contacting zones is related to movements in the directions left, right, in and out, relative to the user.

8. The device of claim 7, wherein the activation of said second contact is related to movment in the down direction relative to the user and wherein said third and fourth contact are related to the up movement relative to the user.

9. The device of claim 6, wherein the movement in at least one direction is commanded by vocal commands.

10. The device of claim 9, wherein said second contact allows enabling or disabling said vocal command of a movement in said at least one direction.
